(19) United States
(12) Patent Application Publication
(10) Pub. No.: US 2013/0217156 A1
(43) Pub. Date: Aug. 22, 2013

(54) METHOD, MASK AND SYSTEM FOR MANUFACTURING SOLAR CELL

(71) Applicant: SUMITOMO HEAVY INDUSTRIES, LTD., (US)

(72) Inventor: Tomohiro Soga, Kanagawa (JP)

(73) Assignee: SUMITOMO HEAVY INDUSTRIES, LTD., Tokyo (JP)

(21) Appl. No.: 13/772,731

(22) Filed: Feb. 21, 2013

(30) Foreign Application Priority Data
Feb. 21, 2012 (JP) 2012-035538

(51) Int. Cl. H01L 21/66

(52) U.S. Cl. CPC H01L 22/12
USPC 438/14; 118/720; 118/696

(57) ABSTRACT

A method of manufacturing a solar cell according to an aspect includes detecting a positioning pattern that includes at least a part of an ion implantation pattern in which an ion is implanted into a predetermined region of a solar cell substrate, and performing relative positioning between a process unit and the solar cell substrate, wherein the process unit executes a predetermined process based on the detected positioning pattern when the predetermined process is executed to the solar cell substrate.

### BACKGROUND OF THE INVENTION

1. Field Invention

The present invention relates to a method, a mask and a system for manufacturing a solar cell.

2. Description of the Related Art

In manufacturing a solar cell, in the case where a substrate is processed in multiple steps successively, usually alignment of the substrate is performed in each step. For example, there has been known a technology in which an impurity is implanted into a predetermined region of the substrate using an ion beam based on a reference mark formed on the substrate in advance.

### SUMMARY OF THE INVENTION

In order to solve the above problems, a method of manufacturing a solar cell according to an aspect of the present invention includes: detecting a positioning pattern that includes at least a part of an ion implantation pattern in which an ion is implanted into a predetermined region of a solar cell substrate; and performing relative positioning between a process unit and the solar cell substrate, wherein the process unit executes a predetermined process based on the detected positioning pattern when the predetermined process is executed to the solar cell substrate.

Another aspect of the present invention is a mask for manufacturing a solar cell. This mask for manufacturing a solar cell is a mask used when implanting an ion into a solar cell substrate, and includes a predetermined mask pattern. The predetermined mask pattern includes a first mask pattern that corresponds to a contact electrode of a solar cell, and a second mask pattern used for forming a positioning pattern of the substrate.

Still another aspect of the present invention is a system for manufacturing a solar cell. This system for manufacturing a solar cell includes: a retrieving unit for retrieving information of a positioning pattern that includes at least a part of an ion implantation pattern in which an ion is implanted into a predetermined region of a solar cell substrate; a positioning unit for performing relative positioning between a process unit and the solar cell substrate, wherein the process unit executes a process based on the retrieved positioning pattern when a predetermined process is executed to the solar cell substrate; and a process unit for executing the predetermined process to the predetermined region of the positioned substrate.

### BRIEF DESCRIPTION OF THE DRAWINGS

FIG. 1 is a pattern diagram of a schematic configuration of a part of a manufacturing system according to this embodiment;

FIG. 2 is a pattern diagram of a configuration of an ion implantation device according to this embodiment;

FIGS. 3A to 3C are pattern diagrams illustrating a change of impurity concentration inside a substrate by a method of ion implantation according to this embodiment;

FIG. 4 is a top view of an exemplary mask for manufacturing a solar cell used in the ion implantation device according to this embodiment;

FIG. 5 is a flowchart schematically illustrating a method of positioning a substrate according to this embodiment;

FIG. 6 is an enlarged view of a region A in FIG. 4; and

FIGS. 7A to 7C are views of a principal part of a mask for manufacturing a solar cell, which forms modifications of a positioning pattern.

### DETAILED DESCRIPTION OF THE INVENTION

The invention will now be described by reference to the preferred embodiments. This does not intend to limit the scope of the present invention, but to exemplify the invention.

In the case where a position of a reference mark formed on a substrate in advance is detected by a recognition unit such as a camera, and a region to be processed of the substrate in each step is determined based on that position, a detection error accumulates in each step. Therefore, there is still room for improvement in accuracy of substrate positioning.

An exemplary object according to an aspect of the present invention is to provide a technology for improving the accuracy of substrate positioning in each process of manufacturing a solar cell.

Embodiments for carrying out the present invention are described herein in details. Note that configurations described herein are only exemplary, and are not intended to limit the scope of the present invention in any way.

In manufacturing a solar cell or a semiconductor device such as an LED, in the case where multiple processes are executed to a substrate, an accurate alignment of the substrate is required in each process. For example, for manufacturing a solar cell, there has been devised a technology in which a contact region having a high impurity concentration is formed in a part of an emitter, and a finger (comb) electrode is formed on a surface of the substrate to align with the position of the contact region, using a printing device, or the like. As a method of implanting an ion selectively into a part of the substrate to form the contact region having a high impurity concentration (also called the selective emitter), a method such as photolithography, printing or a hard mask can be used. Using such a method, by performing ion implantation after masking a region not requiring ion implantation, a selective ion implantation pattern that corresponds to an unmasked region is formed in a predetermined region of the substrate.

The ion implantation pattern as above and the finger electrode formed subsequently need to be aligned accurately with each other. In general, as a method of achieving alignment between the two, there is a method of using a positioning marking formed in advance on a wafer substrate using a laser, for example, or an edge such as a substrate corner. By each of the ion implantation device and the printing device detecting such a marking or a substrate edge with a CCD camera, for example, the positional accuracy can be ensured between the two.

Nevertheless, when using such a method, a mechanism for recognizing the marking is required on each of the ion implantation device and the printing device, resulting in an increase of an overall cost of the manufacturing system. Furthermore, the relative position needs to be aligned between a marking position and an ion implantation pattern, and between a marking position and a finger electrode pattern on both of the devices. In addition, an error that occurs on each device is accumulated directly, which may affect accuracy of overlapping of both patterns and cause quality degradation.

Therefore, in view of such problems, the present inventor devised the following aspect.

A method of manufacturing a solar cell according to this embodiment includes detecting a positioning pattern that includes at least a part of an ion implantation pattern in which an ion is implanted into a predetermined region of a substrate, and positioning the substrate in a predetermined process based on the detected positioning pattern when the predetermined process is executed to the substrate.

According to this aspect, it is not necessary to form a positioning marking in advance on the substrate using a laser, for example, but positioning of the substrate becomes possible by using the ion implantation pattern. In particular, when there is a step of implanting an ion into the substrate in the steps of manufacturing a solar cell, any ineffectual step in the manufacturing can be avoided by using the ion implantation pattern formed in the step of implanting an ion in the positioning. For example, formation of a part (e.g. a laser marking) on the substrate that does not basically contribute to a product performance, or detection of a laser marking in the step of implanting an ion can be eliminated.

Furthermore, in the step of positioning, the substrate positioning is performed based on the ion implantation pattern in a subsequent process. Therefore, an accumulation of positioning errors can be restrained compared with the case where a region to be processed of the substrate in each step is determined based on a predetermined position of the substrate. As a result, accuracy of substrate positioning is improved.

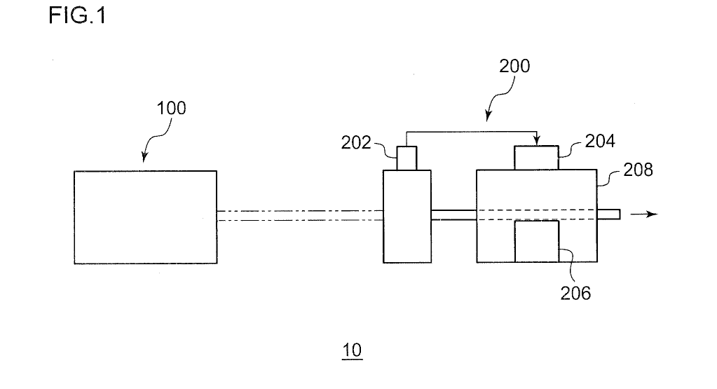

FIG. 1 is a pattern diagram of a part of schematic configuration of a manufacturing system according to this embodiment. In FIG. 1, a configuration of a system mainly used for implanting ions and forming a finger electrode (hereinafter, referred to as a contact electrode) in the steps of manufacturing a solar cell is illustrated.

A solar cell manufacturing system 10 in FIG. 1 includes an ion implantation device 100 and a printing device 200, as multiple process devices.

The ion implantation device 100 forms an ion implantation pattern in which an ion is implanted into a predetermined region of a substrate. A detailed configuration of the ion implantation device 100 is described below. The substrate on which the ion implantation pattern is formed by the ion implantation device 100 is conveyed to the printing device 200 via a conveyer robot, for example.

The printing device 200 includes a detection unit 202, a retrieving unit 204, a positioning unit 206, and a process unit 208. The detection unit 202 detects a positioning pattern, which includes at least a part of an ion implantation pattern formed on the substrate that has been conveyed. The retrieving unit 204 retrieves information of the detected positioning pattern. The positioning unit 206 positions the substrate, on which a contact electrode is formed, based on the retrieved positioning pattern when a contact electrode is formed as a predetermined process to the substrate. The process unit 208 forms a contact electrode in a predetermined region of the positioned substrate.

As the detection unit 202, for example, a CCD camera is used. The positioning unit 206 performs positioning of a substrate based on a control signal sent from the retrieving unit 204, so that an electrode pattern to be printed and an ion implantation pattern are aligned with each other. As the positioning unit 206, a manipulator such as a robot arm or an XY stage may be applicable. Note that the detection unit 202 may also be provided in a device separate from the printing device 200. For example, the detection unit 202 may also be provided in the ion implantation device 100. In this case, information on the detected positioning pattern may be stored in a storage unit (for example, a memory chip) of a conveyer tray that houses the substrate, or an on-line communication unit that connects the devices may allow the information to be retrieved by the retrieving unit 204 of the printing device 200 in the subsequent step.

Furthermore, in the above description, the positioning of the substrate is performed by adjusting the position of the substrate; however, it is not limited to this configuration, as long as the relative positioning between the process unit for executing a predetermined process and the substrate may be performed. For example, the substrate may be always stopped at a predetermined position, and the process unit may be moved appropriately based on the retrieved positioning pattern of the substrate to perform the relative positioning between the substrate and the process unit. The relative positioning between the substrate and the process unit may also be performed by moving both the substrate and the process unit based on the retrieved positioning pattern of the substrate. Specifically, for example, the relative positioning between the substrate and the process unit may be performed by adjusting the position of a print screen of the process unit 208 inside the printing device 200.

Then, the ion implantation device and the ion implantation pattern including the positioning pattern are described below.

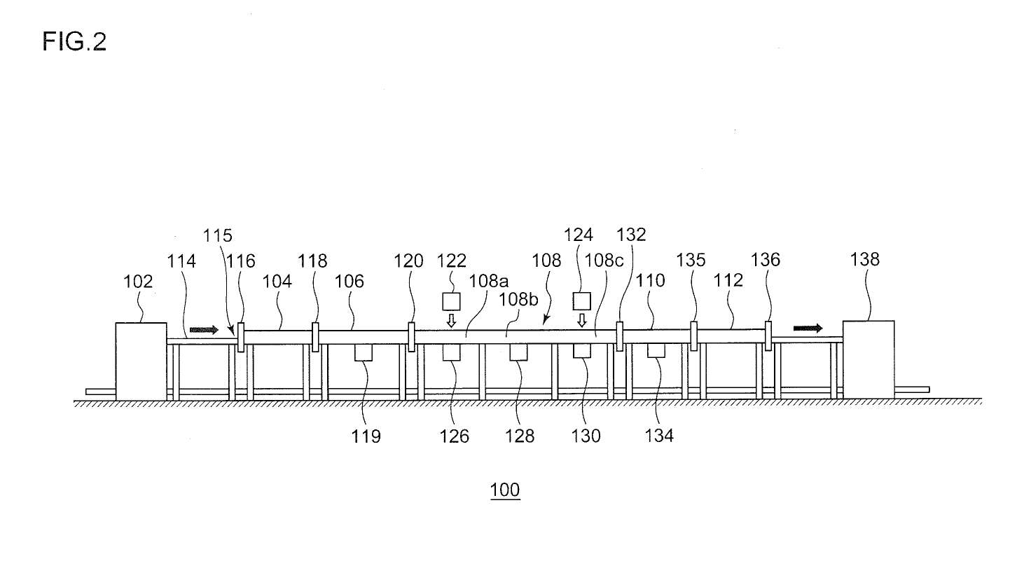

FIG. 2 is a pattern diagram of a configuration of the ion implantation device 100 according to this embodiment. As in FIG. 2, the ion implantation device 100 is a device for forming an ion implantation pattern, including a positioning pattern, on the substrate according to this embodiment. The substrate is conveyed while being housed in a carrier. The ion implantation device 100 includes a load lock chamber (hereinafter, referred to as LC) 104, process chambers (hereinafter, referred to as PCs) 108a and 108c, three buffer chambers (hereinafter, referred to as BCs) 106, 108b and 110, and an unload lock chamber (hereinafter, referred to as ULC) 112. The LC 104 temporary houses a carrier conveyed from a conveyer robot 102 and includes a roughing mechanism for linking atmosphere with vacuum and a vent mechanism using nitrogen, or the like. The PCs 108a and 108c are maintained in a vacuum or a near vacuum condition and include ion implantation sources 122 and 124, respectively. The BCs 106, 108b and 110 are arranged before and after the PCs, include a mask drive mechanism inside, and can be maintained in a vacuum or a near vacuum condition. The ULC 112 temporary keeps a carrier when the carrier is discharged out of the vacuum chamber, and includes a vent mechanism using nitrogen, or the like, for linking vacuum with atmosphere.

Here, the BCs 106, 108b and 110 are installed for alleviating an influence from linking with a vacuum condition, and for stabilizing pressure in the PCs 108a and 108c, and therefore may be omitted by changing the size of LC and PCs and by rearranging the mask drive mechanism to a different position.

Furthermore, the ion implantation device 100 includes a mount unit 114 on which a carrier conveyed from a previous step by the conveyer robot 102 is mounted, and a conveyer unit 115 which conveys the above-described carrier from the mount unit 114 to each chamber. As the previous step, there is a step of forming a rough structure (texture) on the substrate surface. This is a step performed to realize scattering of light on the substrate surface in order to increase absorption of the light by a solar cell. The conveyer unit 115 is realized, for example, by a belt drive system. The conveyer unit 115 according to this embodiment is provided so as to allow a carrier to move in a linear and consecutive manner inside the ion implantation device 100.

In the ion implantation device 100 in FIG. 2, the carrier is mounted on the mount unit 114. The carrier mounted on the mount unit 114 is sent out to the LC 104 by the conveyer unit 115. When the carrier is conveyed into the LC 104, a gate valve 116 between the mount unit 114 and the LC 104 is closed. When the LC 104 reaches a predetermined degree of roughing vacuum by a roughing vacuum pump connected to the LC 104, a gate valve 118 between the BC 106 and the LC 104 is opened. Then, after the carrier is sent out to the BC 106, the gate valve 118 is closed, and the LC 104 is vented with nitrogen, or the like, for taking in the next carrier.

Since the BC 106 is always maintained at high vacuum inside by a turbo molecular pump (hereinafter, referred to as TMP) 119, the carrier taken into the BC 106 instantaneously reaches a high vacuum atmosphere. When the BC 106 reaches a predetermined degree of vacuum, a gate valve 120 provided between the BC 106 and a vacuum chamber 108 in which an ion implantation is performed is opened, and the carrier is conveyed on a belt from the BC 106 to inside the vacuum chamber 108. Subsequently, the gate valve 120 is closed.

The vacuum chamber 108 has no gate valve arranged in the middle, and is configured as three processing chambers, the PC 108a, the BC 108b and the PC 108c, which are linked in a high vacuum. The ion implantation sources 122 and 124, to which a different condition can be set, are arranged to the PCs 108a and 108c, respectively. Furthermore, three TMPs 126, 128 and 130, respectively corresponding to the PC 108a, the BC 108b and the PC 108c are provided. The TMPs 126, 128 and 130 are capable of turning the vacuum chamber 108 into a vacuum condition.

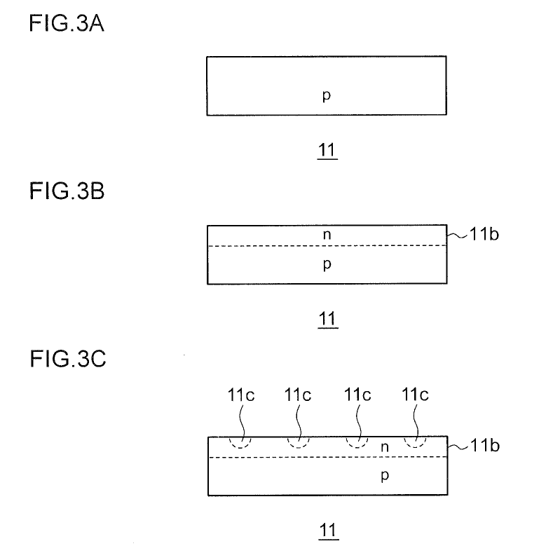

FIGS. 3A to 3C are pattern diagrams illustrating a change of impurity concentration inside a substrate in an ion implantation method according to this embodiment. Hereinafter, the case where a solar cell substrate 11 is a p-type silicon wafer (FIG. 3A) is described, which may also be an n-type silicon wafer or any other types of semiconductor substrate.

The ion implantation source 122 ionizes a PH₃ gas including an n-type impurity by an arc discharge or a high-frequency discharge. The ion implantation source 122 accelerates the ionized gas in the electric field and implants the ionized gas into the entire surface of the substrate 11 conveyed into the PC 108a of the vacuum chamber 108. Accordingly, as in FIG. 3B, an n layer 11b is formed on the entire surface of the substrate 11.

Subsequently, a carrier that houses the substrate 11 is conveyed into the PC 108c via the BC 108b. Within the PC 108c, a mask for manufacturing a solar cell is arranged between the ion implantation source 124 and the substrate 11.

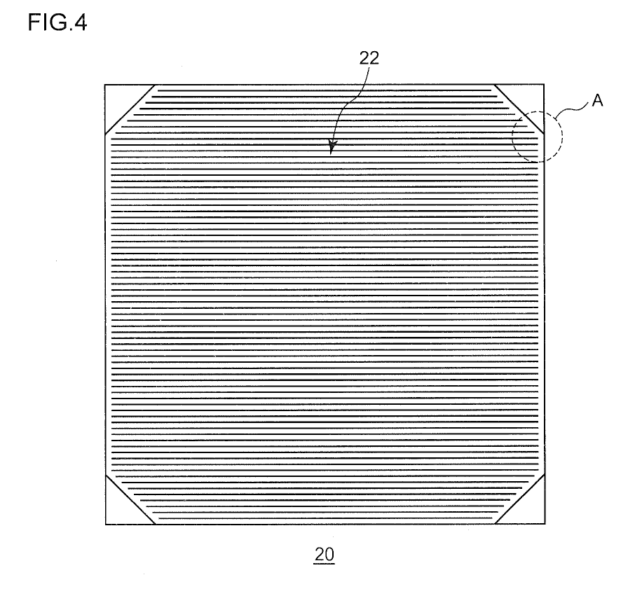

FIG. 4 is a top view of an exemplary mask for manufacturing a solar cell used in an ion implantation device according to this embodiment. A mask 20 for manufacturing a solar cell (hereinafter, referred to as mask 20) includes a predetermined mask pattern 22, and is used when ion implantation is performed to the solar cell substrate 11. The ion implantation source 124 ionizes a PH₃ gas including an n-type impurity by an arc discharge or a high-frequency discharge, and accelerates the ionized gas in the electric field. The ion implantation source 124 implants an ion that has passed through the mask pattern 22 of the mask 20 into the predetermined region on the surface of the substrate 11. Accordingly, as in FIG. 3C, an n+ layer 11c having a higher impurity concentration than the n layer 11b is formed in a predetermined region of the surface of the substrate 11. Such an emitter structure is called the selective emitter layer, which contributes to reducing the contact resistance between the contact electrode, to be formed in a subsequent step of the manufacturing of a solar cell, and the substrate 11.

When the two-phased step of implanting is completed, a gate valve 132 is opened. After the carrier is conveyed to the next BC 110, the gate valve 132 is closed. In the BC 110, a TMP 134 is provided for realizing a predetermined degree of vacuum. When the gate valve 132 is closed, a gate valve 135 placed between the BC 110 and the ULC 112 is opened, the carrier is conveyed to the ULC 112, and the gate valve 135 is closed. Subsequently, the ULC 112 is vented with nitrogen, or the like, a gate valve 136 is opened subsequently, and the carrier is sent out to an atmosphere. Once the carrier is sent out to the atmosphere, the gate valve 136 is closed again, and in order to send out the next carrier, the ULC 112 is rough-pumped by a roughing vacuum pump. On the downstream side of the ion implantation device 100, a conveyer robot 138 is arranged for conveying the carrier holding the ion-implanted substrate 11 to a subsequent step. Then, the carrier conveyed from the ion implantation device 100 is housed in the conveyer robot 138 and conveyed to the printing device 200, a subsequent step, one by one.

Note that in the ion implantation device 100 in FIG. 2, an ion implantation source is used for implanting an ion to the entire surface of the substrate, while the other ion implantation source and a fixed mask for manufacturing a solar cell are used for implanting an ion to a predetermined region of the substrate. It is also possible to realize an entire-surface ion implantation and a partial ion implantation, for example, by combining one ion implantation source and a movable mobile mask for manufacturing a solar cell.

As described above, the ion implantation device 100 is capable of forming, on the substrate, an ion implantation pattern that has an impurity concentration higher than in other region and corresponds to the mask pattern of the mask 20. Since this ion implantation pattern has an impurity concentration higher than in other region, and thus has a different condition from the surrounding region. Therefore, the pattern based on the impurity concentration difference may be captured as an image by photographing the substrate surface with the above-described CCD camera. Accordingly, the positioning pattern may be detected. Note that it is not limited to a CCD camera, and any device or method capable of detecting a difference in concentration of impurity distributed in the substrate may be used. Furthermore, in case it is difficult to differentiate an ion implantation pattern from other region by a CCD camera due to existence of a film on the substrate surface, such as an antireflection film, the definition of the pattern may be improved by adjusting a method of irradiation including an adjustment of the light source, wavelength and intensity of an infrared ray or other light, and use of the diffuse reflection method.

Furthermore, the same method may be used in the case where the type of impurity is different between the ion implantation pattern and other region or where there is a difference in level between patterns. In such cases as well, the detection unit 202 is not particularly limited to a CCD camera, and any device capable of detecting a difference in the type or the shape of impurity distributed in the substrate may be used.

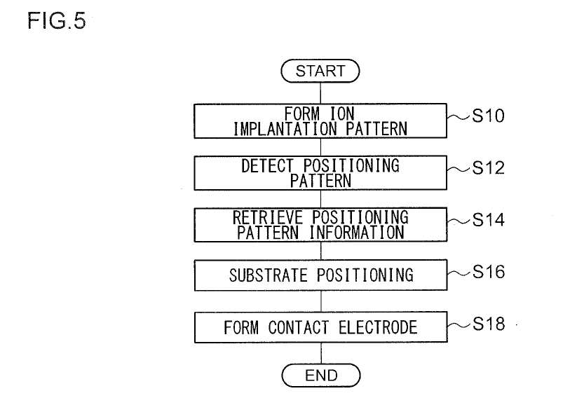

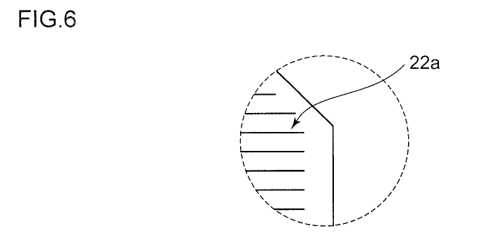

FIG. 5 is a flowchart schematically illustrating a method of positioning a substrate according to this embodiment. As described above, the ion implantation pattern having the impurity concentration higher than in other region is formed in the predetermined region of the substrate by using the ion implantation device 100 (S10). Subsequently, steps of performing the annealing treatment to the substrate and forming the antireflection film are carried out. Then, the surface of the substrate 11 is photographed using a detection device such as a CCD camera, and the positioning pattern including at least a part of the ion implantation pattern is detected (S12). When the mask for manufacturing a solar cell is a mask pattern as in FIG. 4, by photographing the entire surface of the substrate, the entire ion implantation pattern may be used as the positioning pattern. Furthermore, depending on the shape of the pattern of a mask for manufacturing a solar cell, the positioning pattern may be detected by photographing a part of the substrate. FIG. 6 is an enlarged view of the region A in FIG. 4. A mask pattern 22a in a region in FIG. 6 is a part that is a non-repetitious pattern of the mask pattern 22 in FIG. 4. Accordingly, the positioning of the substrate becomes possible without having to detect the entire ion implantation pattern. Furthermore, since the region to be photographed is smaller, a camera may be downsized while image processing may be reduced.

Then, the printing device 200, a device in the subsequent step of the ion implantation device 100, retrieves information of the positioning pattern (S14), performs positioning of the substrate based on the positioning pattern (S16), and forms a contact electrode so as to overlap with the ion implantation pattern (S18). Accordingly, alignment accuracy is improved when forming a contact electrode by overlapping the contact region of the substrate 11.

As described above, since the positioning of the substrate for forming the contact electrode is performed based on the positioning pattern that includes at least a part of the ion implantation pattern, an error in alignment is decreased when forming the contact electrode in the predetermined region of the substrate.

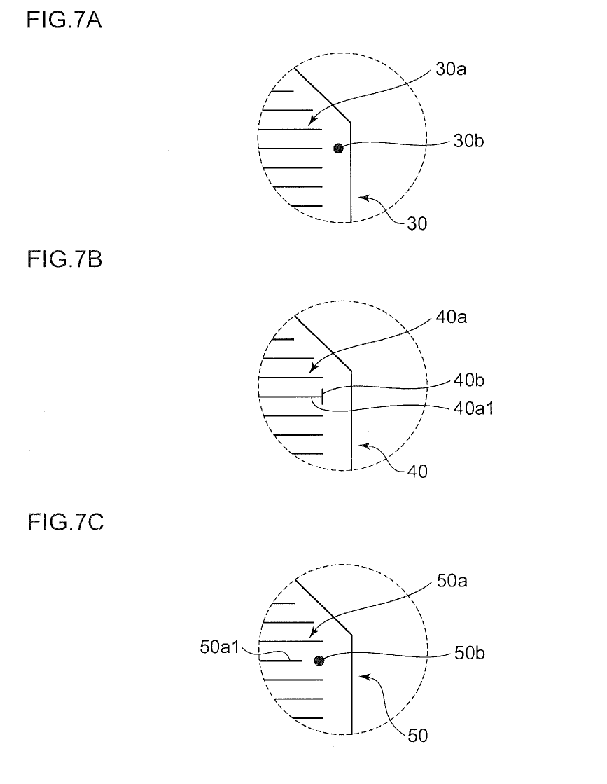

FIGS. 7A to 7C are views of a principal part of a mask for manufacturing a solar cell, which forms modifications of the positioning pattern. Any of the principal parts of a mask for manufacturing a solar cell is an enlarged view of a region corresponding to the region A in FIG. 4.

A mask 30 for manufacturing a solar cell (hereinafter, referred to as mask 30) in FIG. 7A, similar to the mask 20 in FIG. 4, is used when ion implantation is performed to the solar cell substrate. The mask 30 includes a first mask pattern 30a that corresponds to the contact electrode of the solar cell, and a second mask pattern 30b used for forming the positioning pattern for the substrate. The second mask pattern 30b is a dot pattern that is formed closer to an edge of the substrate compared to the first mask pattern 30a. By using the mask 30 having such second mask pattern 30b, not only the ion implantation pattern that corresponds to the contact electrode but also the positioning pattern can be formed simultaneously in the step of implanting ions.

A mask 40 for manufacturing a solar cell in FIG. 7B includes a first mask pattern 40a that corresponds to the contact electrode of the solar cell, and a second mask pattern 40b used for forming the positioning pattern for the substrate. The second mask pattern 40b is a small slit connecting with a slit 40a1 of the first mask pattern 40a, and is formed in the direction of crossing the slit 40al.

A mask 50 for manufacturing a solar cell in FIG. 7C includes a first mask pattern 50a that corresponds to the contact electrode of the solar cell, and a second mask pattern 50b used for forming the positioning pattern for the substrate. The second mask pattern 50b is a dot pattern that is formed in a part where a slit 50a1 of the first mask pattern 50a is cut off and shortened.

The ion implantation pattern formed by using each mask in FIG. 4 and FIGS. 7A to 7C includes a first pattern that corresponds to the contact electrode of the solar cell and a second pattern used as the positioning pattern. The first pattern and the second pattern are integral as the ion implantation pattern. By performing the positioning in the subsequent electrode printing process based on the second pattern, the position of the first pattern is also determined with accuracy. Therefore, the alignment accuracy is improved when the contact electrode is formed by overlapping on the contact region of the substrate, in which the impurity concentration is increased by ion implantation, using the printing device 200, for example.

Note that the second mask pattern can be either a pattern completely different from the first mask pattern or a pattern that includes a part of the first mask pattern.

As above, the present invention has been described by referring to the above-described embodiments; however, the present invention is not intended to be limited to the above-described embodiments and any embodiment that appropriately combines configurations or alters a configuration in the above-described embodiments is also included in the present invention. Furthermore, in the method, the mask, and the system of manufacturing a solar cell according to the embodiments, it is also possible to add a modification including various types of design changes to the embodiments based on the knowledge of those skilled in the art, and any embodiment with such a modification may also be included in the scope of the present invention.

It should be understood that the invention is not limited to the above-described embodiment, but may be modified into various forms on the basis of the spirit of the invention. Additionally, the modifications are included in the scope of the invention.

Priority is claimed to Japanese Patent Application No. 2012-035538, filed Feb. 21, 2012, the entire content of which is incorporated herein by reference.

What is claimed is:

1. A method of manufacturing a solar cell, comprising:
detecting a positioning pattern that includes at least a part of an ion implantation pattern in which an ion is implanted into a predetermined region of a solar cell substrate; and
performing relative positioning between a process unit and the solar cell substrate, wherein
the process unit executes a predetermined process based on the detected positioning pattern when the predetermined process is executed to the solar cell substrate.

2. The method of manufacturing a solar cell according to claim 1, wherein
the ion implantation pattern includes a first pattern that corresponds to a contact electrode of a solar cell, and a second pattern used as the positioning pattern.

3. The method of manufacturing a solar cell according to claim 1, wherein
the positioning pattern is a part that is a non-repetitious pattern of the ion implantation pattern.

4. The method of manufacturing a solar cell according to claim 1, wherein
the positioning pattern is detected based on a difference in concentration of impurity distributed in the solar cell substrate in the detecting.

5. The method of manufacturing a solar cell according to claim 2, wherein
the positioning pattern is detected based on a difference in concentration of impurity distributed in the solar cell substrate in the detecting.

6. The method of manufacturing a solar cell according to claim 3, wherein
the positioning pattern is detected based on a difference in concentration of impurity distributed in the solar cell substrate in the detecting.

7. The method of manufacturing a solar cell according to claim 1, wherein
the positioning pattern is detected based on a difference in type of impurity distributed in the solar cell substrate in the detecting.

8. The method of manufacturing a solar cell according to claim 2, wherein
the positioning pattern is detected based on a difference in type of impurity distributed in the solar cell substrate in the detecting.

9. The method of manufacturing a solar cell according to claim 3, wherein
the positioning pattern is detected based on a difference in type of impurity distributed in the solar cell substrate in the detecting.

10. A mask for manufacturing a solar cell, the mask being used when implanting an ion into a solar cell substrate, the mask comprising:
a predetermined mask pattern, wherein
the predetermined mask pattern includes a first mask pattern that corresponds to a contact electrode of a solar cell, and a second mask pattern used for forming a positioning pattern of the substrate.

11. A system for manufacturing a solar cell, comprising:
a retrieving unit for retrieving information of a positioning pattern that includes at least a part of an ion implantation pattern in which an ion is implanted into a predetermined region of a solar cell substrate;
a positioning unit for performing relative positioning between a process unit and the solar cell substrate, wherein the process unit executes a process based on the retrieved positioning pattern when the predetermined process is executed to the solar cell substrate; and
a process unit for executing the predetermined process to the predetermined region of the solar cell substrate.

12. The system for manufacturing a solar cell according to claim 11, wherein
the process unit forms an electrode so as to overlap with at least a part of the ion implantation pattern.
